(19) United States
(12) Patent Application Publication
(10) Pub. No.: US 2017/0236930 A1
(43) Pub. Date: Aug. 17, 2017

(54) VERTICAL DOUBLE-DIFFUSED METAL-OXIDE SEMICONDUCTOR FIELD-EFFECT TRANSISTOR AND MANUFACTURING METHOD THEREFOR

(71) Applicant: WUXI CHINA RESOURCES HUAJING MICROELECTRONICS CO., LTD., Wuxi (CN)

(72) Inventors: Xiaoru Sun, Wuxi (CN); Hongwei Zhou, Wuxi (CN); Mengbo Ruan, Wuxi (CN)

(73) Assignee: WUXI CHINA RESOURCES HUAJING MICROELECTRONICS CO, Wuxi (CN)

(21) Appl. No.: 15/323,108

(22) PCT Filed: Dec. 31, 2014
(86) PCT No.: PCT/CN2014/095925

§ 371 Date: Dec. 30, 2016

(30) Foreign Application Priority Data
Sep. 29, 2014 (CN) 201410514651.2

(51) Int. Cl. H01L 29/78; H01L 29/08; H01L 29/66; H01L 29/36; H01L 29/10

(52) U.S. Cl. CPC H01L 29/7802; H01L 29/36; H01L 29/1095; H01L 29/66712; H01L 29/0865

(57) ABSTRACT

The present invention provides a vertical double-diffused metal-oxide semiconductor field-effect transistor and a manufacturing method. The manufacturing method comprises: providing a substrate of a first conductive type; growing a first epitaxial layer of the first conductive type above the substrate; forming column regions of the first conductive type and column regions of a second conductive type spaced in a staggered manner above the first epitaxial layer; forming a third epitaxial layer of the first conductive type above the column regions of the first conductive type, and forming a well region of the second conductive type above the column regions of the second conductive type; forming a gate region on a surface of the third epitaxial layer; forming a source region of the first conductive type in the well region of the second conductive type; and forming a gate metal layer, a source metal layer, and a drain metal layer.

### CROSS REFERENCE TO RELATED APPLICATIONS

This application is a US National Stage of International Application PCT/CN2014/095925, filed on Dec. 31, 2014, designating the United States, and claiming priority to Chinese Patent Application No. 201410514651.2, filed with State Intellectual Property Office, P.R.C. on Sep. 29, 2014, the entire content of which is incorporated herein by reference.

### TECHNICAL FIELD

The present disclosure relates to a power semiconductor device manufacturing technology field, and more particularly, to a vertical double-diffused metal-oxide semiconductor field-effect transistor and a manufacturing method therefor.

### BACKGROUND

Vertical double-diffused metal-oxide semiconductor field-effect transistors (VDMOS) have been widely used in analog circuits, especially driving circuits, and more especially a high-voltage power section, due to advantages of such as small switch loss, high input impedance, low driving power, good frequency characteristics, and high linearity of transconductance.

FIG. 1 is a cross-sectional structure view of a conventional VDMOS device. The conventional VDMOS device may include an N-type semiconductor substrate 101, a drift layer 102 located above the substrate 101, a gate electrode G located on a surface of the drift layer 102, a P-type well region 103 located within the drift layers 102 on both sides of the gate electrode G, an N-type source region 104 located within the P-type well region 103, a source metal layer 108 located on a surface of the N-type source region 104, and a drain metal layer 109 located on a back surface of the substrate 100.The gate electrode G includes a gate oxide layer 105, and a polysilicon layer 106 and a gate metal layer 107 which are sequentially located above the gate oxide layer 105. An on-resistance of the conventional VDMOS device is primarily a resistance of the drift layer 102, and a withstand capability of the drift layer 102 is determined by its thickness and doping concentration. In order to reduce the on-resistance, the thickness of the drift layer 102 in the VDMOS device needs to be reduced, or the doping concentration of the drift layer 102 needs to be increased, which may result in a decrease in a withstand voltage of the VDMOS device. The on-resistance of the conventional VDMOS device is restricted by the silicon limit with the increase in the withstand voltage, which is called “silicon limit”. The on-resistance increases as the withstand voltage increases with a relationship of a power of 2.5. As can be seen, the conventional VDMOS device has a disadvantage of high on-resistance.

### SUMMARY

In view of this, a vertical double-diffused metal-oxide semiconductor field-effect transistor and a manufacturing method therefor are provided in the present disclosure in order to reduce the on-resistance of the device.

To achieve the above objectives, the following technical schemes are adopted in the present disclosure.

One aspect of the present disclosure features a manufacturing method of a vertical double-diffused metal-oxide semiconductor field-effect transistor, and the manufacturing method includes the following steps:

providing a substrate of a first conductive type;

growing a first epitaxial layer of the first conductive type above the substrate of the first conductive type, the first epitaxial layer having a first resistivity;

forming a column region of the first conductive type and column regions of a second conductive type spaced in a staggered manner above the first epitaxial layer, the column regions of the second conductive type being located on both sides of the column region of the first conductive type, the column region of the first conductive type having a second resistivity, and the second resistivity being less than the first resistivity;

forming a third epitaxial layer of the first conductive type above the column region of the first conductive type, the third epitaxial layer having a third resistivity, and forming well regions of the second conductive type above the column regions of the second conductive type, the well regions of the second conductive type being coupled to the column regions of the second conductive type, and the third resistivity being equal to the second resistivity;

forming a gate region on a surface of the third epitaxial layer;

forming source regions of the first conductive type in the well regions of the second conductive type; and

forming a gate metal layer above the gate region, forming source metal layers above the source regions of the first conductive type, and forming a drain metal layer under the substrate of the first conductive type.

According to an example, a thickness of the first epitaxial layer is 10˜30 μm, the first resistivity is 5˜20 ohm·cm, a thickness of the column regions of the first conductive type is 15-40 μm, and the second resistivity is 2˜10 ohm·cm.

According to an example, a thickness of the third epitaxial layer is 5˜10 μm, and a doped-ion type and a doping concentration of the third epitaxial layer are the same as a doped-ion type and a doping concentration of the column regions of the first conductive type.

According to an example, the forming the column region of the first conductive type and the column regions of the second conductive type spaced in a staggered manner comprises a multi-epitaxial method or a deep trench epitaxial method.

According to an example, the first conductive type is an N type, and the second conductive type is a P type; or the first conductive type is a P type, and the second conductive type is an N type.

Another aspect of the invention features a vertical double-diffused metal-oxide semiconductor field-effect transistor, and the field-effect transistor comprises:

a substrate of a first conductive type;

a drain metal layer located under the substrate of the first conductive type;

a first epitaxial layer of the first conductive type located above the substrate of the first conductive type, the first epitaxial layer having a first resistivity;

a column region of the first conductive type and column regions of a second conductive type spaced in a staggered manner above the first epitaxial layer, the column regions of the second conductive type being located on both sides of the column region of the first conductive type, the column region of the first conductive type having a second resistivity, and the second resistivity being less than the first resistivity;

a third epitaxial layer of the first conductive type located above the column region of the first conductive type, and a gate region and a gate metal layer located on a surface of the third epitaxial layer, the third epitaxial layer having a third resistivity, and the third resistivity being equal to the second resistivity;

well regions of the second conductive type located above the column regions of the second conductive type, the well regions of the second conductive type being coupled to the column regions of the second conductive type; and

source regions of the first conductive type located in the well regions of the second conductive type, and source metal layers located above the source regions of the first conductive type.

According to an example, a thickness of the first epitaxial layer is 10˜30 μm, the first resistivity is 5˜20 ohm·cm, a thickness of the column regions of the first conductive type is 15-40 μm, and the second resistivity is 2˜10 ohm·cm.

According to an example, a thickness of the third epitaxial layer is 5˜10 μm, and a doped-ion type and a doping concentration of the third epitaxial layer are the same as a doped-ion type and a doping concentration of the column regions of the first conductive type.

According to an example, the first conductive type is an N type, and the second conductive type is a P type; or the first conductive type is a P type, and the second conductive type is an N type.

Compared with the prior art, the advantages of the technical schemes in the present disclosure are described below.

A vertical double-diffused metal-oxide semiconductor field-effect transistor and a manufacturing method therefor are provided in the present disclosure. Compared with the conventional VDMOS device, by adding an additional epitaxial layer that is the third epitaxial layer and by forming column regions of a first conductive type and column regions of a second conductive type that are spaced in a staggered manner for introducing a transverse electric field, the column regions of the device may be completely consumed at a small turn-off voltage. The breakdown voltage is merely related to a thickness of the column regions and a critical electric field, which breaks the “silicon limit” of the conventional VDMOS device, so that the on-resistance is slowly increased with the increase of the withstand voltage. Hence, at the same withstand voltage, a doping concentration of the column regions may be increased by an order of magnitude, which greatly reduces the on-resistance; and since a first epitaxial layer is formed between the third epitaxial layer and the substrate of the first conductive type to be used as a drift layer of the low-voltage VDMOS, the on-resistance is small, which may further reduce the total on-resistance of the device under a condition that the thickness of the device is fixed.

### BRIEF DESCRIPTION OF DRAWINGS

Further description of embodiments of the present disclosure or prior arts will be described below with reference to accompanying drawings to make features and advantages of the present disclosure become apparent, in which,

FIG. 1 is a cross-sectional structure view of a conventional VDMOS device in accordance with a prior art;

FIG. 2 is a cross-sectional structure view of a vertical double-diffused metal-oxide semiconductor field-effect transistor in accordance with an example of the present disclosure;

FIG. 3 is a flowchart of a manufacturing method of a vertical double-diffused metal-oxide semiconductor field-effect transistor in accordance with an example of the present disclosure;

FIG. 4A is a cross-sectional structure view corresponding a block S1 shown in FIG. 3;

FIG. 4B is a cross-sectional structure view corresponding to a block S2 shown in FIG. 3;

FIG. 4C is a first cross-sectional structure view corresponding to the block S3 shown in FIG. 3 in an embodiment;

FIG. 4D is a second cross-sectional structure view corresponding to the block S3 shown in FIG. 3 in an embodiment;

FIG. 4E is a first cross-sectional structure view corresponding to the block S3 shown in FIG. 3 in another embodiment;

FIG. 4F is a second cross-sectional structure view corresponding to the block S3 shown in FIG. 3 in another embodiment;

FIG. 4G is a structure cross-sectional view corresponding to a block S4 shown in FIG. 3;

FIG. 4H is a cross-sectional structure view corresponding to a block S5 shown in FIG. 3;

FIG. 4I is a cross-sectional structure view corresponding to a block S6 shown in FIG. 3; and

FIG. 4J is a cross-sectional structure view corresponding to a block S7 shown in FIG. 3.

### DETAILED DESCRIPTION

To make objects, technical details and advantages of the examples of the present disclosure apparent, technical solutions according to the examples of the present disclosure will be described clearly and completely as below in conjunction with the accompanying drawings of examples of the present disclosure. It is apparent that the described embodiments are only a part of but not all of exemplary examples of the present invention. Based on the described examples of the present disclosures, various other examples can be obtained by those of ordinary skill in the art without creative work and those examples shall fall into the protection scope of the present invention.

In the present disclosure, the first conductive type is an N type, and the second conductive type is a P type; or the first conductive type is a P type, and the second conductive type is an N type. For ease of description, a substrate of the first conductive type of the structure provided in the examples of the present disclosure is an N-type substrate, a first epitaxial layer of the first conductive type is an N-type first epitaxial layer, a column region of the first conductive type is an N-type column region, column regions of the second conductive type are P-type column regions, well regions of the second conductive type are P-type well regions, and source regions of the first conductive type are N-type source regions.

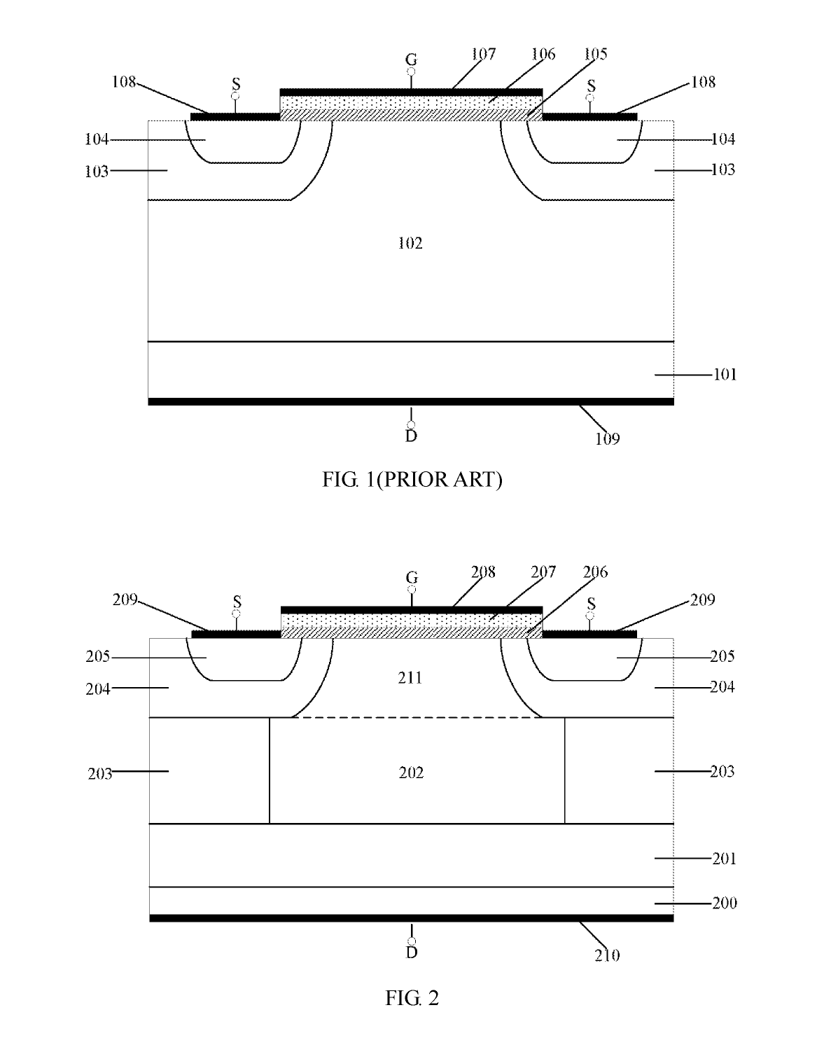

FIG. 2 is a cross-sectional structure view of a vertical double-diffused metal-oxide semiconductor field-effect transistor in accordance with an example of the present disclosure. As shown in FIG. 2, the field-effect transistor includes an N-type substrate 200; a drain metal layer 210 located under the N-type substrate 200; an N-type first epitaxial layer 201 located above the N-type substrate 200; an N-type column region 202 and P-type column regions 203 that are spaced in a staggered manner above the N-type first epitaxial layer 201, wherein the P-type column regions 203 are located on both sides of the N-type column regions 202, and the N-type column region 202 has a second resistivity; an N-type third epitaxial layer 211 located above the N-type column region 202, and a gate region and a metal layer 208 located on a surface of the N-type third epitaxial layer 211, wherein the gate region includes a gate oxide layer 206 and a polysilicon layer 207; P-type well regions 204 located above the P-type column regions 203, wherein the P-type well regions 204 are coupled to the P-type column regions 203; and N-type source regions 205 located in the P-type well regions 204, and source metal layers 209 located above the N-type source regions 205; wherein the N-type first epitaxial layer 201 has a first resistivity, the N-type third epitaxial layer 211 has a third resistivity, the second resistivity is less than the first resistivity, and the third resistivity is equal to the second resistivity.

In this example, the N-type substrate 200 may be an N-type single-crystal silicon doped with a N-type heavily-doped concentration, and N-type ions may be antimony or arsenic. In an example, the N-type substrate 200 may serve as a drain region, and the drain region and the drain metal layer 210 constitute a drain electrode D.

In an example, the N-type first epitaxial layer 201 may be an N-type epitaxial single-crystal silicon doped with a N-type lightly-doped concentration, and dopant ions may be phosphorus or arsenic. Alternatively, a thickness of the N-type first epitaxial layer 201 may be 10˜30 μm, and the resistivity of the N-type first epitaxial layer 201 may be 5˜20 ohm·cm.

In the above examples of the present disclosure, the field-effect transistor includes the N-type column region 202 and the P-type column regions 203 that are located above the N-type first epitaxial layer 201 and spaced in a staggered manner. The P-type column regions 203 are located on both sides of the N-type column region 202, the N-type column region 202 has a second resistivity, and the charge balance should be satisfied by the P-type column regions 203 and the N-type column region 202. Alternatively, a thickness of the N-type column region 202 may be 15-40 μm, the resistivity of the N-type column region 202 may be 2˜10 ohm·cm, and the resistivity of the P-type column regions 203 may be 2˜10 ohm·cm. Dopant ions of the N-type column region 202 are the same as dopant ions of the first epitaxial layer 201, and the dopant ions of the P-type column regions 203 may be boron.

In this example, the N-type third epitaxial layer 211 may be an N-type epitaxial single-crystal silicon layer, and a doped-ion type and a doping concentration of the N-type third epitaxial layer 211 are the same as a doped-ion type and a doping concentration of the N-type column region 202. Alternatively, a thickness of the N-type third epitaxial layer 211 may be 5˜10 μm, and a resistivity of the N-type third epitaxial layer 211 may be 2˜10 ohm·cm.

The gate region includes a gate oxide layer 206 and a polysilicon layer 207. The gate oxide layer 206 is located on a surface of the N-type third epitaxial layer 211, optionally has a thickness of 500˜2000 angstroms and includes at least a silicon oxide. The polysilicon layer 207 is located above the gate oxide layer 206, and optionally has a thickness of 1000˜7000 angstroms. The gate metal layer 208 is deposited on a surface of the polysilicon layer 207, and the gate region and the gate metal layer 208 constitute a gate electrode G.

In this example, the P-type well region 204 is located within the N-type third epitaxial layer 211 on both sides of the gate electrode G with an upper surface in partial contact with the gate oxide layer 206, and in contact with the P-type column regions 203 and the N-type column region 202. A width of the P-type well regions 204 is greater than a width of the P-type column regions 203. Dopant ions of the P-type well region 204 are the same as dopant ions of the P-type column regions 203.

The N-type source regions 205 are N-type heavily-doped ion regions located in the top of the P-type well regions 204 with upper surfaces in partial contact with the gate oxide layer 206. The N-type source regions 205 and the source metal layers above surfaces of the N-type source regions 205 constitute a source electrode S.

A vertical double-diffused metal-oxide semiconductor field-effect transistor and a manufacturing method therefor are provided in the present disclosure. Compared with the conventional VDMOS device, by adding an additional epitaxial layer that is the third epitaxial layer and by forming column regions of a first conductive type and column regions of a second conductive type that are spaced in a staggered manner for introducing a transverse electric field, the column regions of the device may be completely consumed at a small turn-off voltage. A breakdown voltage is merely related to a thickness of the column regions and a critical electric field, which breaks the “silicon limit” of the conventional VDMOS device, so that the on-resistance is slowly increased with the increase of the withstand voltage. Hence, at the same withstand voltage, the doping concentration of the column regions may be increased by an order of magnitude, which greatly reduces the on-resistance; and since the first epitaxial layer is formed between the third epitaxial layer and the substrate of the first conductive type to be used as a drift layer of the low-voltage VDMOS, the on-resistance is small, which may further reduce the total on-resistance of the device under a condition that the thickness of the device is fixed.

In the following, a manufacturing method for implementing the above-described field-effect transistor device according to the present disclosure will be described in detail.

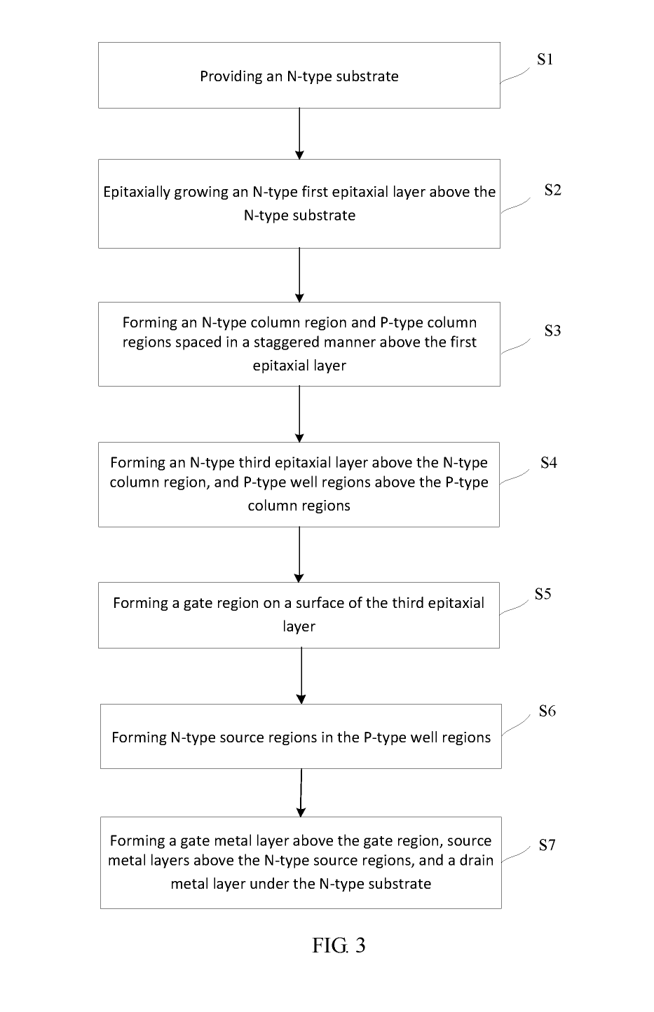

FIG. 3 is a flowchart of a manufacturing method of a vertical double-diffused metal-oxide semiconductor field-effect transistor according to an example of the present disclosure. As shown in FIG. 3, the manufacturing method may include the following blocks.

At block S1, an N-type substrate is provided.

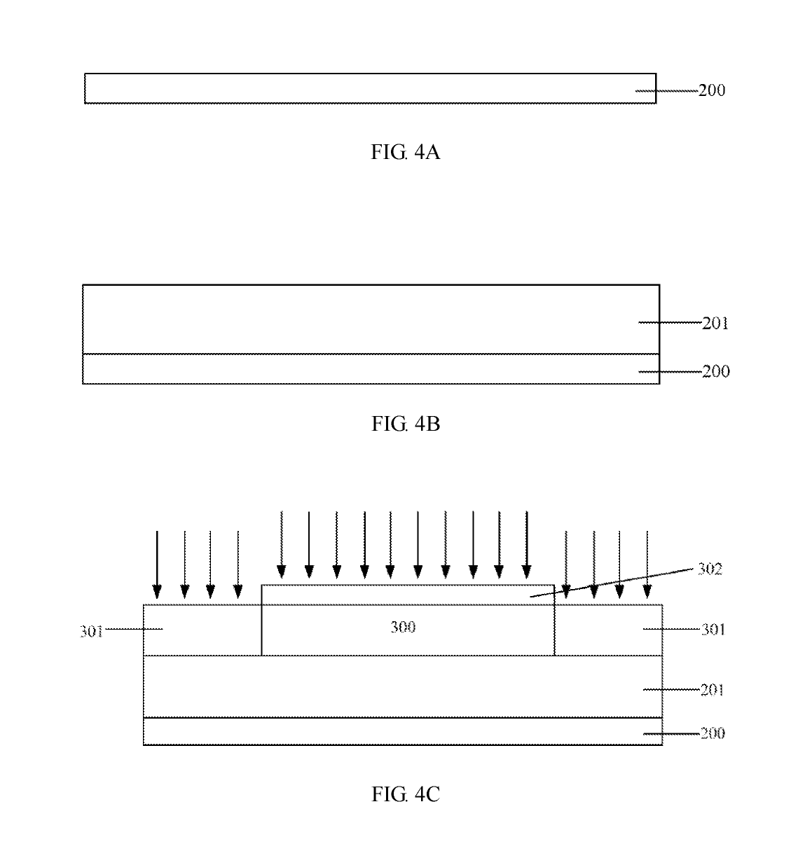

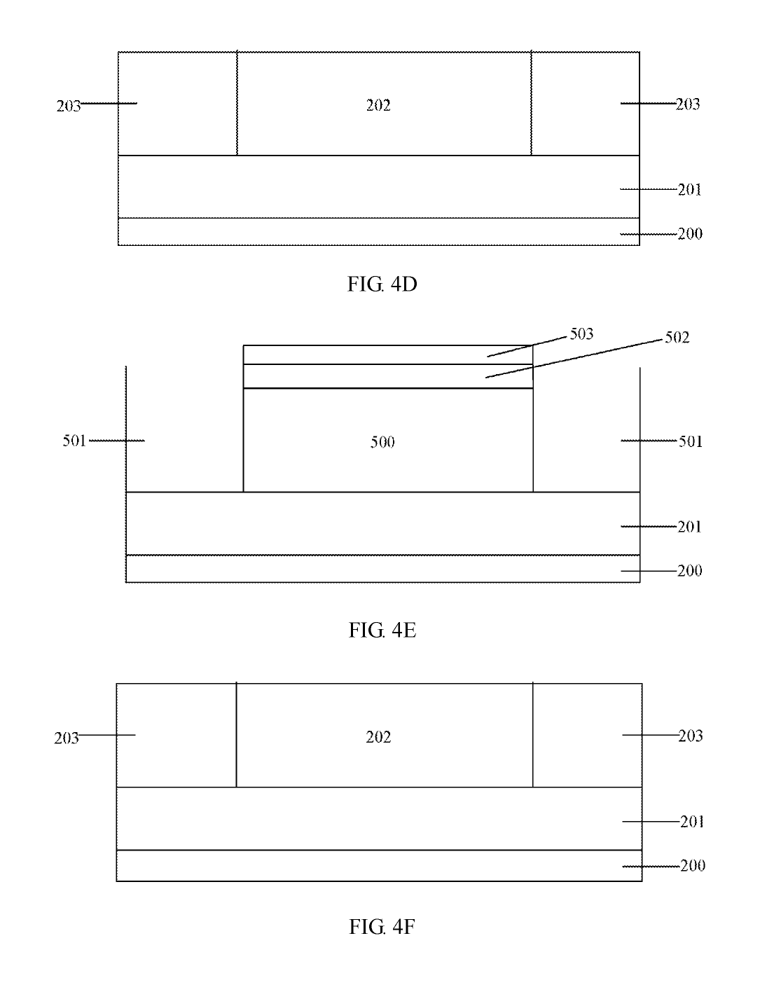

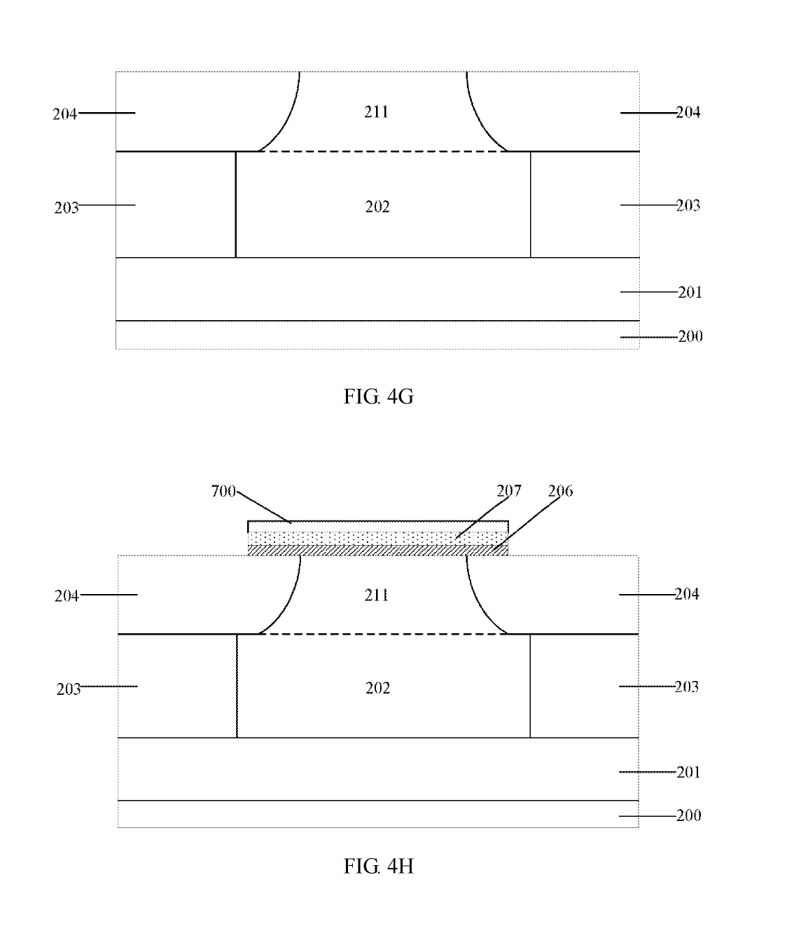

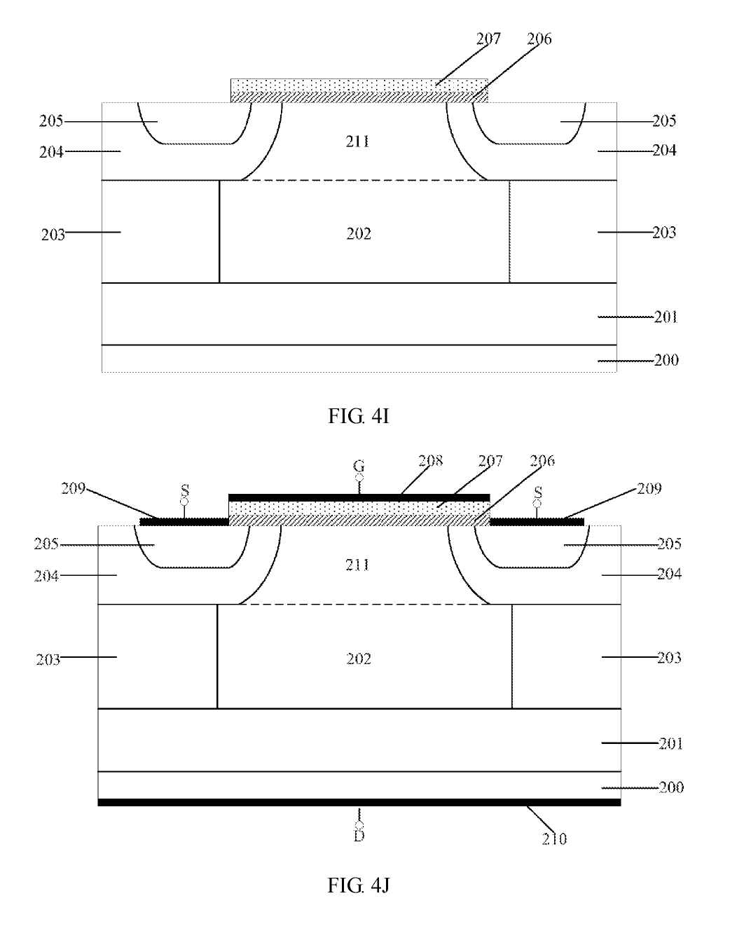

Referring to FIG. 4A, in this example, an N-type ion heavily-doped is performed on a single-crystal silicon wafer to form an N+ type semiconductor substrate 200. The N-type ions may be phosphorus or arsenic.

At block S2, an N-type first epitaxial layer is epitaxial grown above the N-type substrate.

Referring to FIG. 4B, in this example, an N-type single-crystal silicon layer is epitaxial grown above the N-type substrate 200 in an epitaxial method to form an N-type first epitaxial layer 201. The N-type first epitaxial layer 201 has a first resistivity, and dopant ions of the N-type first epitaxial layer 201 are the same as ions of the N-type substrate 200. Alternatively, a thickness of the N-type first epitaxial layer 201 is 10˜30 μm, and a resistivity of the N-type first epitaxial layer 201 is 5˜20 ohm·cm.

At block S3, an N-type column region and P-type column regions spaced in a staggered manner are formed above the first epitaxial layer.

In this example of the present disclosure, a multi-epitaxial method and a deep trench epitaxial method are adopted for forming the N-type column region and the P-type column regions that are spaced in a staggered manner.

Referring to FIGS. 4C-4D, a multi-epitaxial method is adopted for forming the N-type column region 202 and the P-type column regions 203.

Specially, the N-type column region 202 and the P-type column regions 203 are formed by multiple epitaxies, wherein each epitaxy accompanies with photolithography and ion implantation.

Referring to FIG. 4C, in this method, a thinner second resistivity sub-epitaxial layer 300 is epitaxially grown above the first epitaxial layer 201, and dopant ions of the sub-epitaxial layer 300 are the same as dopant ions of the N-type substrate 200. A photolithography adhesive layer 302 is formed above the second resistivity sub-epitaxial layer 300, and the photolithography adhesive layer 302 is exposed by a mask plate having patterns of P-type doped regions 301, such that the patterns of the P-type doped regions 301 are formed on both sides of a surface of the photolithography adhesive layer 302. Then, the photoresist layer having the patterns of the P-type doped regions 301 is served as a mask, and an ion injection method is adopted for forming the P-type doped regions 301. In this block, the injected ions may be boron.

Referring to FIG. 4D, the photolithography adhesive layer 302 is removed. The above-described processes are repeated 1-2 times, that is, to epitaxially grow the thinner second resistivity sub-epitaxial layer, to perform the photolithography and to perform the ion implantation until that the N-type column region 202 and the P-type column regions 203 are up to a predetermined thickness. The photoresist layer on a surface of the last layer of the second resistivity sub-epitaxial layer is removed, and a thermal push-down on surfaces of the P-type doped regions 301 in the last layer of the second resistivity sub-epitaxial layer is performed, such that the adjacent P-type doped regions 301 are joined together in a longitudinal direction to form the P-type column regions 203, thereby forming the P-type column regions 203 and the N-type column region 202 that are spaced in a staggered manner.

Since a depth to width ratio of the semi-superjunction VDMOS is smaller, voids are not easily formed during the epitaxial growing procedure when adopting the deep trench epitaxial method to form the N-type column region 202 and the P-type column regions 203. Compared to the multi-epitaxial method, process difficulty may be reduced to lower process cost. Therefore, the deep trench epitaxial method may be adopted for forming the N-type column regions 202 and the P-type column regions 203.

Referring to FIGS. 4E-4F, a deep trench epitaxial method is adopted for forming the N-type column region 202 and the P-type column regions 203.

Specially, deep trenches may be etched on both sides of the N-type epitaxial layer of a predetermined thickness, and then a P-type epitaxial growth may be performed in the deep trenches.

Referring to FIG. 4E, in the method, a second epitaxial layer 500 of a predetermined thickness is epitaxially grown above the first epitaxial layer 201. The second epitaxial layer 500 has a second resistivity, and the dopant ions of the second epitaxial layer 500 are the same as the dopant ions of the N-type substrate 200. A hard mask layer 502 is formed above the second epitaxial layer 500, and the material of the hard mask layer 502 is silicon oxide or silicon nitride. In the example of the present disclosure, the silicon oxide hard mask layer 502 is used, the forming method is a thermal oxidation method, and an optional thickness is 4000˜10000 angstroms. A photoresist pattern 503 is formed on the hard mask layer 502, and the photoresist pattern 503 covers the middle portion of the hard mask layer 502. The photoresist pattern 503 is used as a mask to remove the hard mask layer 502 which is not protected by the photoresist pattern 503 through a dry etching process, and openings are formed at both ends. A wet etching process is performed to remove the photoresist pattern 503, and a dry etching process is performed along the openings until that the first epitaxial layer 201 is exposed to form the P-type column region deep trenches 501.

Referring to FIG. 4F, the P-type column regions 203 are formed in the P-type column region deep trenches 501, the manufacturing method of the P-type column regions 203 may be a selective epitaxial method, and the material of the P-type column regions 203 may be an epitaxial single-crystal silicon. Alternatively, the resistivity is 5˜20 ohm·cm. The etching process is performed to remove the hard mask layer 502 and expose the N-type column region 202, and thus the P-type column regions 203 and the N-type column region 202 that are spaced in a staggered manner are formed.

Referring to FIG. 4D or FIG. 4F, the P-type column regions 203 are located on both sides of the N-type column region 202. The N-type column region 202 has a second resistivity, the second resistivity is greater than the first resistivity, and the charge balance is satisfied by the P-type column regions 203 and the N-type column region 202. Alternatively, a thickness of the N-type column region 202 may be 15-40 μm, the resistivity of the N-type column regions 202 may be 2˜10 ohm·cm, the resistivity of the P-type column regions 203 may be 2˜10 ohm·cm. The dopant ions of the N-type column region 202 are the same as the dopant ions of the first epitaxial layer 201, and the dopant ions of the P-type column regions 203 may be boron.

At block S4, an N-type third epitaxial layer is formed above the N-type column region, and P-type well regions are formed above the P-type column regions.

Referring to FIG. 4G, in this example, an N-type third epitaxial layer 211 is formed above the N-type column region 202 and the P-type column regions 203 in the epitaxial method. The third epitaxial layer 211 has a third resistivity, the material of the third epitaxial layer 211 may be a single-crystal silicon, and the third resistivity is equal to the second resistivity. A doped-ion type and a doping concentration of the third epitaxial layer 211 are the same as a doped-ion type and a doping concentration of the N-type column regions 202. Alternatively, a thickness of the third epitaxial layer 211 is 5˜10 μm, and the resistivity of the third epitaxial layer 211 is 2˜10 ohm·cm. The P-type doped regions are formed on both sides of the third epitaxial layer 211 by photolithography and ion implantation, and then a diffusion and a thermal push well are performed on P-type impurity to form P-type well regions 204. The P-type well regions 204 are in contact with the P-type column regions 203 and the N-type column region 202, and a width of the P-type well regions 204 is greater than a width of the P-type column regions 203. The dopant ions of the P-type well regions 204 are the same as the dopant ions of the P-type column regions 203.

At block S5, a gate region is formed on a surface of the third epitaxial layer.

Referring to FIG. 4H, in this example, a gate oxide layer 206 is grown above the third epitaxial layer 211 at one time. The gate oxide layer 206 includes at least a silicon oxide and optionally has a thickness of 500˜2000 angstroms. Both ends of a lower surface of the gate oxide layer 206 are in partial contact with the P-type well regions. A polysilicon layer 207 is deposited above the gate oxide layer 206. The polysilicon layer 207 optionally has a thickness of 1000˜7000 angstroms. The polysilicon layer 207 may be formed in a low-pressure chemical vapor deposition method. A photolithography adhesive layer 700 having a gate region pattern is formed on a surface of the polysilicon layer 207 by adopting a photolithography process. By using the photolithography adhesive layer 700 having the gate region pattern as a mask, a dry etching method is adopted for simultaneously etching the polysilicon layer 207 not covered by the photolithography adhesive layer 700 and the gate oxide layer 206 below it, and the photolithography adhesive layer 700 is temporarily retained.

At block S6, N-type source regions are formed in the P-type well regions.

Referring to FIG. 4I, in this example, the photolithography adhesive layer 700 is used as a mask, the N-type impurity is implanted and then annealed to form highly-doped N-type source regions 205, and the photolithography adhesive layer 700 is removed. The N-type source regions 205 are located in the top of the P-type well regions 204, and the upper surfaces of the N-type source regions 205 are in partial contact with the gate oxide layer 206.

At block S7, a gate metal layer is formed above the gate region, source metal layers are formed above the N-type source regions, and a drain metal layer is formed under the N-type substrate.

Referring to FIG. 4J, in this example, a metal layer is deposited on the upper surface and the back surface of the device. A metal chemical vapor deposition method may be used for forming the metal layer. A metal layer formed above the polysilicon layer 207 is a gate metal layer 208, metal layers formed above the N-type source regions 205 are source metal layers 209, and a metal layer formed on the back surface of the N-type substrate 200 is a drain metal layer 210. The gate region and the gate metal layer 208 constitute a gate electrode G, the N-type source regions 205 and the source metal layers 209 constitute source electrodes S, and the N-type substrate 200 and the drain metal layer 210 constitute the drain electrode D.

A vertical double-diffused metal-oxide semiconductor field-effect transistor and a manufacturing method therefor are provided in the present disclosure. Compared with the conventional VDMOS device, by adding an additional epitaxial layer that is the third epitaxial layer and by forming column regions of a first conductive type and column regions of a second conductive type that are spaced in a staggered manner for introducing a transverse electric field, the column regions of the device may be completely consumed at a small turn-off voltage. The breakdown voltage is merely related to a thickness of the column regions and a critical electric field, which breaks the “silicon limit” of the conventional VDMOS device, so that the on-resistance is slowly increased with the increase of the withstand voltage. Hence, at the same withstand voltage, a doping concentration of the column regions may be increased by an order of magnitude, which greatly reduces the on-resistance; and since the first epitaxial layer is formed between the third epitaxial layer and the substrate of the first conductive type to be used as a drift layer of the low-voltage VDMOS, the on-resistance is small, which may further reduce the total on-resistance of the device under a condition that the thickness of the device is fixed.

The above are only preferred examples of the present disclosure is not intended to limit the disclosure within the spirit and principles of the present disclosure, any changes made, equivalent replacement, or improvement in the protection of the present disclosure should contain within the range.

1. A manufacturing method of a vertical double-diffused metal-oxide semiconductor field-effect transistor, comprising:
providing a substrate of a first conductive type;
growing a first epitaxial layer of the first conductive type above the substrate of the first conductive type, the first epitaxial layer having a first resistivity;
forming a column region of the first conductive type and column regions of a second conductive type spaced in a staggered manner above the first epitaxial layer, the column regions of the second conductive type being located on both sides of the column region of the first conductive type, the column region of the first conductive type having a second resistivity, and the second resistivity being less than the first resistivity;
forming a third epitaxial layer of the first conductive type above the column region of the first conductive type, the third epitaxial layer having a third resistivity, and forming well regions of the second conductive type above the column regions of the second conductive type, the well regions of the second conductive type being coupled to the column regions of the second conductive type, and the third resistivity being equal to the second resistivity;
forming a gate region on a surface of the third epitaxial layer;
forming source regions of the first conductive type in the well regions of the second conductive type; and
forming a gate metal layer above the gate region, forming source metal layers above the source regions of the first conductive type, and forming a drain metal layer under the substrate of the first conductive type.

2. The manufacturing method according to claim 1, wherein a thickness of the first epitaxial layer is 10˜30 μm the first resistivity is 5˜20 ohm·cm, a thickness of the column region of the first conductive type is 15˜40 μm and the second resistivity is 2˜10 ohm·cm.

3. The manufacturing method according to claim 1, wherein a thickness of the third epitaxial layer is 5˜10 μm, and a doped-ion type and a doping concentration of the third epitaxial layer are the same as a doped-ion type and a doping concentration of the column regions of the first conductive type.

4. The manufacturing method according to claim 1, wherein the forming the column region of the first conductive type and the column regions of the second conductive type spaced in a staggered manner comprises a multi-epitaxial method or a deep trench epitaxial method.

5. The manufacturing method according to any one of claims 1, wherein the first conductive type is an N type, and the second conductive type is a P type; or the first conductive type is a P type, and the second conductive type is an N type.

6. A vertical double-diffused metal-oxide semiconductor field-effect transistor, comprising:
a substrate of a first conductive type;
a drain metal layer located under the substrate of the first conductive type;
a first epitaxial layer of the first conductive type located above the substrate of the first conductive type, the first epitaxial layer having a first resistivity;
a column region of the first conductive type and column regions of a second conductive type spaced in a staggered manner above the first epitaxial layer, the column regions of the second conductive type being located on both sides of the column region of the first conductive type, the column region of the first conductive type having a second resistivity, and the second resistivity being less than the first resistivity;
a third epitaxial layer of the first conductive type located above the column region of the first conductive type, and a gate region and a gate metal layer located on a surface of the third epitaxial layer, the third epitaxial layer having a third resistivity, and the third resistivity being equal to the second resistivity;
well regions of the second conductive type located above the column regions of the second conductive type, the well regions of the second conductive type being coupled to the column regions of the second conductive type; and
source regions of the first conductive type located in the well regions of the second conductive type, and source metal layers located above the source regions of the first conductive type.

7. The field-effect transistor according to claim 6, wherein a thickness of the first epitaxial layer is 10˜30 μm, the first resistivity is 5˜20 ohm·cm, a thickness of the column regions of the first conductive type is 15-40 μm and the second resistivity is 2˜10 ohm·cm.

8. The field-effect transistor according to claim 6, wherein a thickness of the third epitaxial layer is 5˜10 μm, and a doped-ion type and a doping concentration of the third epitaxial layer are the same as a doped-ion type and a doping concentration of the column regions of the first conductive type.

9. The field-effect transistor according to any one of claims 6, wherein the first conductive type is an N type, and the second conductive type is a P type; or the first conductive type is a P type, and the second conductive type is an N type.
